(19) United States
(12) Patent Application Publication
(10) Pub. No.: US 2014/0073077 A1
(43) Pub. Date: Mar. 13, 2014

(54) METHOD FOR EPITAXIAL GROWTH OF LIGHT EMITTING DIODE

(71) Applicant: Advanced Optoelectronic Technology, Inc., Hsinchu Hsien (TW)

(72) Inventors: YA-WEN LIN, Hsinchu (TW); SHIH-CHENG HUANG, Hsinchu (TW); PO-MIN TU, Hsinchu (TW)

(73) Assignee: Advanced Optoelectronic Technology, Inc., Hsinchu Hsien (TW)

(21) Appl. No.: 13/958,612

(22) Filed: Aug. 5, 2013

(30) Foreign Application Priority Data
Sep. 12, 2012 (CN) 2012103341140

(51) Int. Cl. H01L 33/00

(52) U.S. Cl. CPC H01L 33/0075
USPC 438/47

(57) ABSTRACT

A method for epitaxial growth of a light emitting diode, includes following steps: providing a substrate; forming a buffer layer on the substrate; forming a first epitaxial layer on the buffer layer in a first temperature; forming a second epitaxial layer on the first epitaxial layer in a second temperature lower than the first temperature, thereby forming a first rough surface on the second epitaxial layer; etching the second epitaxial layer and the first epitaxial layer until a second rough surface is formed on the first epitaxial layer; forming a mask layer on the rough surface of the first epitaxial layer; partly etching the mask layer to form a plurality of protrusions with the first epitaxial layer exposed thereamong; and forming an N-type epitaxial layer, an active layer and a P-type epitaxial layer on the first epitaxial layer in sequence.

### BACKGROUND

1. Technical Field

The disclosure generally relates to a method for epitaxial growth of a light emitting diode, and particularly relates to a method to form a light emitting diode with improved lighting efficiency.

2. Description of Related Art

In recent years, due to excellent light quality and high luminous efficiency, light emitting diodes (LEDs) have increasingly been used as substitutes for incandescent bulbs, compact fluorescent lamps and fluorescent tubes as light sources of illumination devices.

Generally, LED epitaxial layers are formed on a sapphire substrate. Since a lattice constant and a coefficient of thermal expansion of the LED epitaxial layers are quite different from that of the sapphire substrate, threading dislocations will be formed in the LED epitaxial layers, which affects lighting efficiency of the LED. In addition, when the LED epitaxial layers emit light, light emitted to the sapphire substrate is probably absorbed by the sapphire substrate, thereby decreasing the lighting efficiency of the LED epitaxial layers.

What is needed, therefore, is a method for epitaxial growth of a light emitting diode to overcome the above described disadvantages.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 shows a first step of a method for epitaxial growth of a light emitting diode (LED) in accordance with a first embodiment of the present disclosure.

FIG. 2 shows a second step of a method for epitaxial growth of a light emitting diode in accordance with a first embodiment of the present disclosure.

FIG. 3 shows a third step of a method for epitaxial growth of a light emitting diode in accordance with a first embodiment of the present disclosure.

FIG. 4 shows a fourth step of a method for epitaxial growth of a light emitting diode in accordance with a first embodiment of the present disclosure.

FIG. 5 shows a fifth step of a method for epitaxial growth of a light emitting diode in accordance with a first embodiment of the present disclosure.

FIG. 6 shows a sixth step of a method for epitaxial growth of a light emitting diode in accordance with a first embodiment of the present disclosure.

FIG. 7 shows a seventh step of a method for epitaxial growth of a light emitting diode in accordance with a first embodiment of the present disclosure.

FIG. 8 is a top view of the SiO₂ layer in FIG. 7.

FIG. 9 is a top view of the SiO₂ layer in FIG. 7 in accordance with another embodiment.

FIG. 10 shows an eighth step of a method for epitaxial growth of a light emitting diode in accordance with a first embodiment of the present disclosure.

FIG. 11 is a cross-sectional view showing an LED formed by a method for epitaxial growth of a light emitting diode in accordance with a second embodiment of the present disclosure.

FIG. 12 is a cross-sectional view showing an LED formed by a method for epitaxial growth of a light emitting diode in accordance with a third embodiment of the present disclosure.

### DETAILED DESCRIPTION

Embodiments of a method for epitaxial growth of a light emitting diode will now be described in detail below and with reference to the drawings.

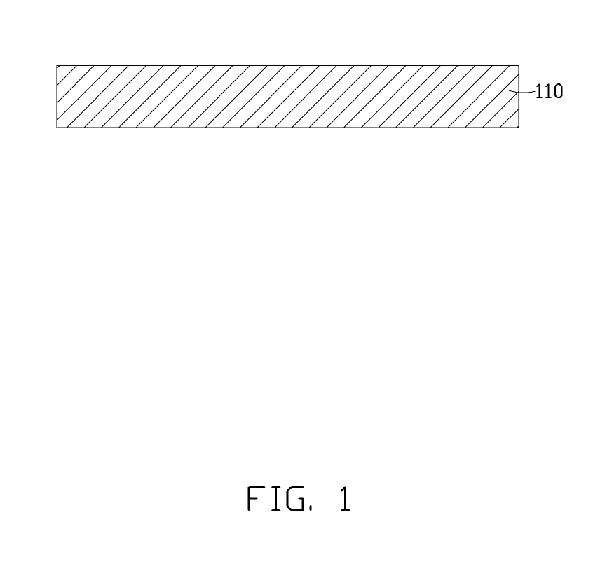

Referring to FIG. 1, a substrate 110 is provided. In this embodiment, the substrate 110 is made of sapphire and the sapphire substrate 110 has a flat upper surface.

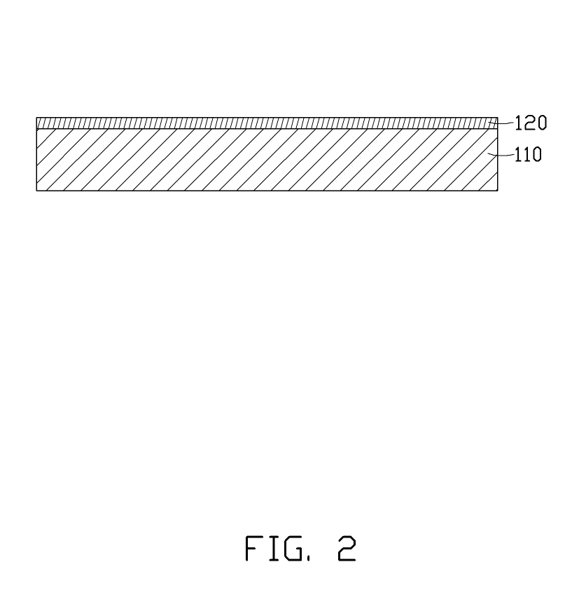

Referring to FIG. 2, a buffer layer 120 is formed on the substrate 110.

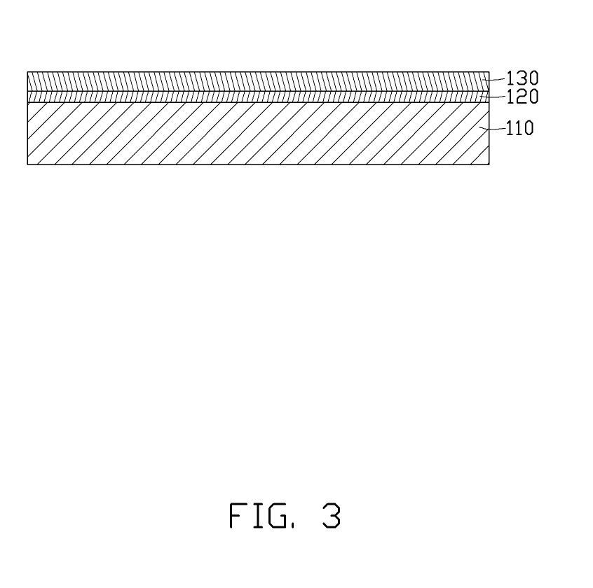

Referring to FIG. 3, a first epitaxial layer 130 is formed on the buffer layer 120 in a first temperature. In this embodiment, the first temperature is in a range from 1100° C. to 1300° C. The first epitaxial layer 130 can be an un-doped GaN layer or an N-type GaN layer.

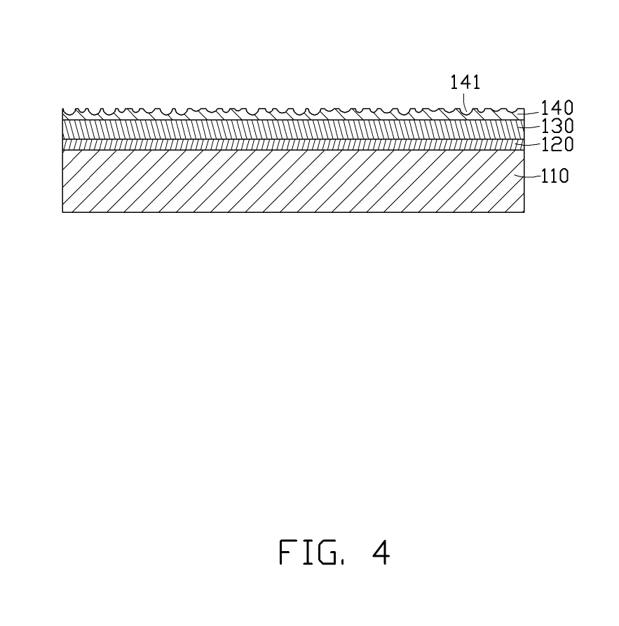

Referring to FIG. 4, a second epitaxial layer 140 is formed on the first epitaxial layer 130 in a second temperature. The second temperature is lower than the first temperature, thereby to cause the second epitaxial layer 140 to form a first rough upper surface 141 at a top of the second epitaxial layer 140. In this embodiment, the second temperature is in a range from 500° C. to 600° C. Similarly, the second epitaxial layer 140 can be an un-doped GaN layer or an N-type GaN layer.

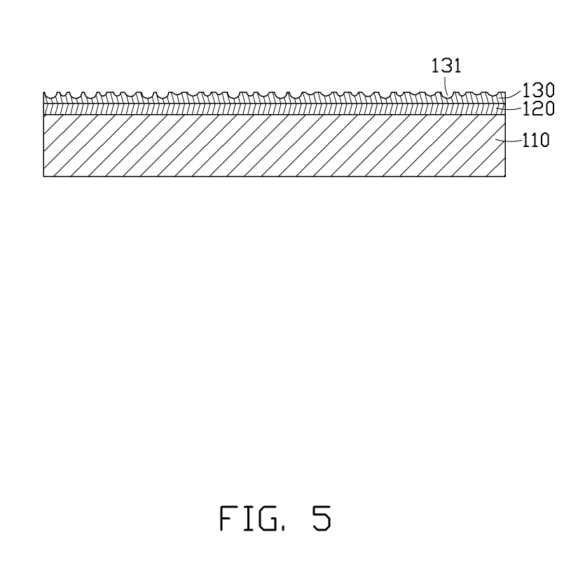

Referring to FIG. 5, the second epitaxial layer 140 and the first epitaxial layer 130 are etched by inductively coupled plasma (ICP) etching, until a pattern of the rough upper surface 141 of the second epitaxial layer 140 is transferred to the first epitaxial layer 130 and a second rough surface 131 is formed on the first epitaxial layer 130. In etching, since an etching thickness of the second epitaxial layer 140 is increased along with lapse of etching time, portions of the second epitaxial layer 140 with a lower thickness will firstly be etched away to expose a corresponding part of the first epitaxial layer 130 therebelow. The exposed part of the first epitaxial layer 130 is continuously etched until the second epitaxial layer 140 is totally etched away. After the second epitaxial layer 140 has been totally etched away, the pattern of the rough surface 141 of the second epitaxial layer 140 is transferred to the first epitaxial layer 130 to form the second rough surface 131. Preferably, the second epitaxial layer 140 and the first epitaxial layer 130 can also be etched by reactive ion etching (RIE), until the pattern of the rough surface 141 of the second epitaxial layer 140 is transferred to the first epitaxial layer 130.

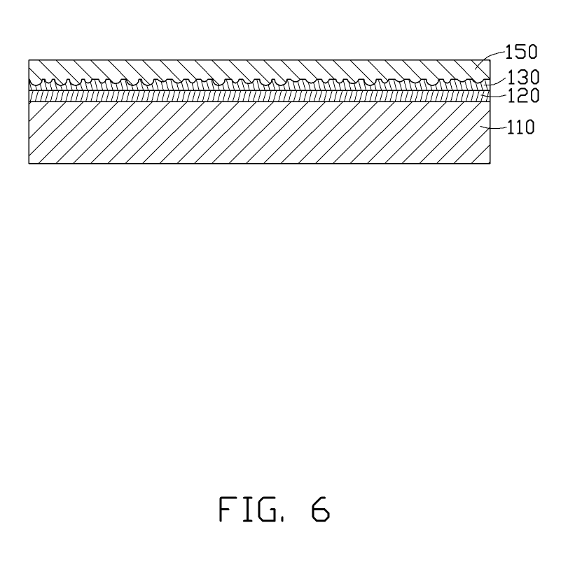

Referring to FIG. 6, a mask layer 150 is formed on the rough surface 131 of the first epitaxial layer 130. In this embodiment, the mask layer 150 is made of SiO₂.

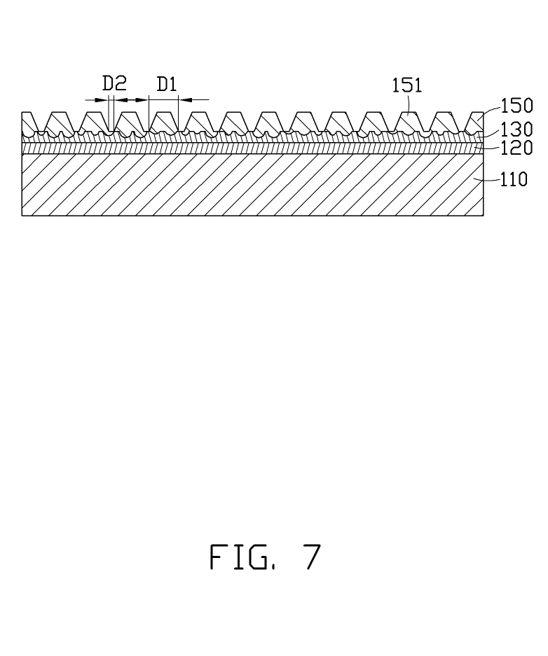

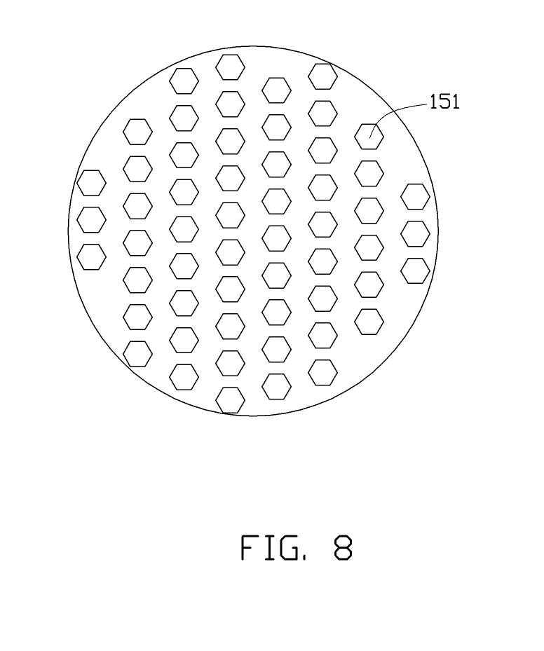

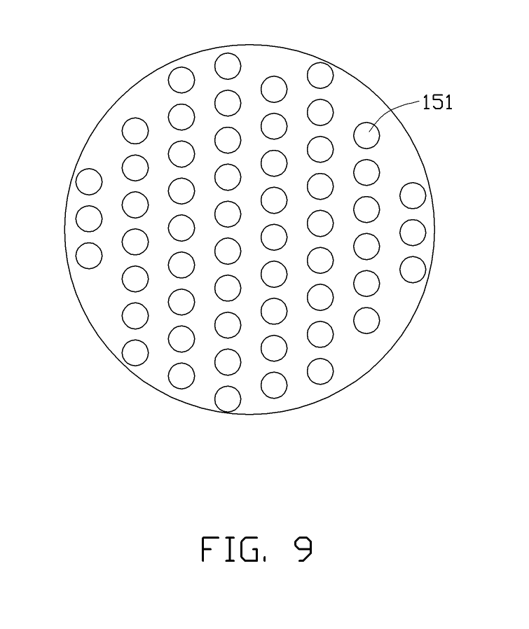

Referring to FIG. 7, an upper surface of the mask layer 150 is etched to expose a part of the first epitaxial layer 130 and form a plurality of first protrusions 151 by an upper portion of the mask layer 150. The first protrusions 151 each can have a circular, rectangular or other polygon-shaped top surface. Referring to FIG. 8, the first protrusions 151 each have a hexagon shaped top surface and are arranged in a matrix. Referring to FIG. 9, the first protrusions 151 each are configured with a circular top surface. A diameter D1 of each of the first protrusions 151 is in a range from 2 μm to 3 μm. Gaps D2 are formed between every two adjacent first protrusions 151. The gaps D2 each have a width between 1 μm to 2 μm. In this embodiment, the first protrusions 151 each have a diameter D1 of 3 μm, and the gaps D2 each between two adjacent first protrusions 151 are 2 μm. In another embodiment, the first protrusions 151 each have a diameter D1 of 2 μm, and the gaps D2 each between two adjacent first protrusions 151 are 1 μm.

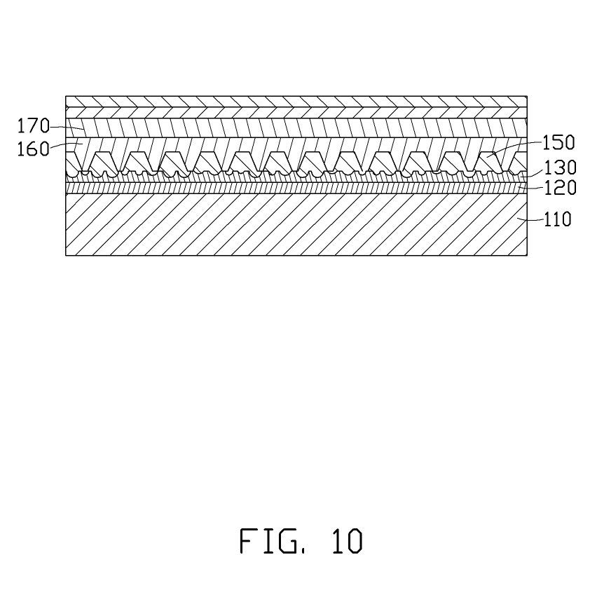

Referring to FIG. 10, an N-type epitaxial layer 160, an active layer 170 and a P-type epitaxial layer 180 are formed on the first epitaxial layer 130 in sequence. In this embodiment, the N-type epitaxial layer 160, the active layer 170 and the P-type epitaxial layer 180 each are made of a material selected from a group consisting of GaN, AlGaN, InGaN and AlInGaN.

In operation, a positive voltage is applied between the P-type epitaxial layer 180 and the N-type epitaxial layer 160, holes in the P-type epitaxial layer 180 and electrons in the N-type epitaxial layer 160 will combine in the active layer 170 and energy is released in a form of light. Since the upper portion of the mask layer 150 has a plurality of first protrusions 151 and the first epitaxial layer 130 has a second rough surface 131, the mask layer 150 and the first epitaxial layer 130 will reflect light from the active layer 170 and make the light travel upwardly. That is, the second rough surface 131 and the first protrusions 151 can avoid the light from being absorbed by the substrate 110 and improve lighting efficiency of the LED chip.

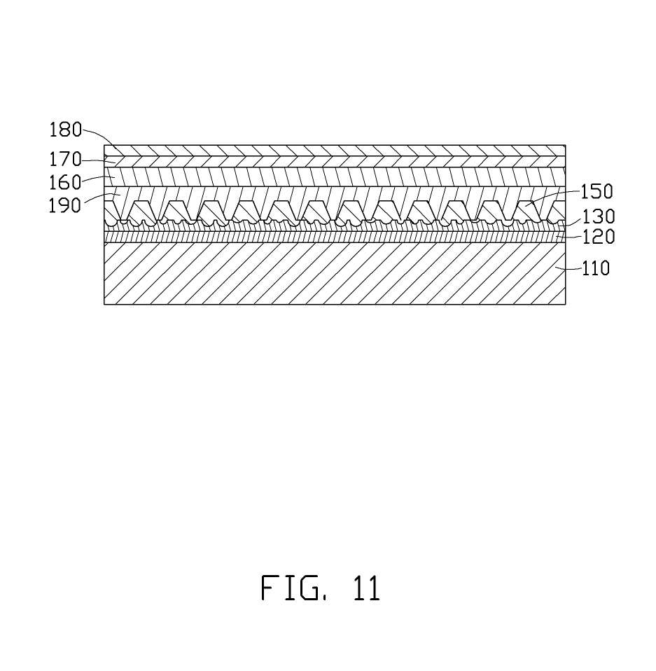

The epitaxial growth method for a light emitting diode is not limited to the embodiment described above. Referring to FIG. 11, after a plurality of first protrusions 151 is formed on the upper surface of the mask layer 150, a cover layer 190 can firstly be formed on the rough surface 131 of the first epitaxial layer 130 and the mask layer 150. Then, the N-type epitaxial layer 160, the active layer 170 and the P-type epitaxial layer 180 are formed on the cover layer 190 in sequence. The cover layer 190 can be an AlN layer and grown in the above mentioned first temperature, i.e., in a range from 1100° C. to 1300° C.

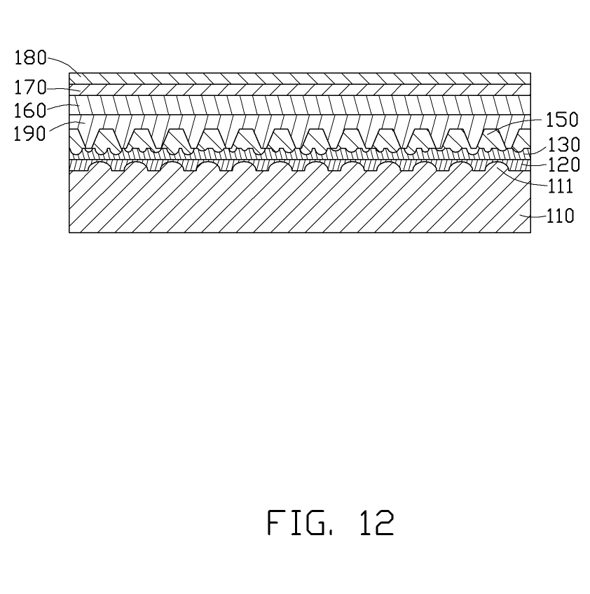

The substrate 110 is not limited to the embodiment described above. Referring to FIG. 12, in still another embodiment, the substrate 110 is a patterned sapphire substrate. An upper surface of the substrate 110 has a plurality of second protrusions 111 arranged in a matrix. The second protrusions 111 each have a hexagon-shaped top surface. And the epitaxial layers can be formed on the patterned substrate 110.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A method for epitaxial growth of a light emitting diode, comprising following steps:
providing a substrate;
forming a buffer layer on the substrate;
forming a first epitaxial layer on the buffer layer in a first temperature;
forming a second epitaxial layer on the first epitaxial layer in a second temperature, the second temperature being lower than the first temperature to form a first rough surface on a top of the second epitaxial layer;
etching the second epitaxial layer and the first epitaxial layer until a pattern of the first rough surface of the second epitaxial layer is transferred to the first epitaxial layer and forming a second rough surface on a top of the first epitaxial layer;
forming a mask layer on the second rough surface of the first epitaxial layer;
partly etching the mask layer to form a plurality of first protrusions with the first epitaxial layer exposed thereamong; and
forming an N-type epitaxial layer, an active layer and a P-type epitaxial layer on the first epitaxial layer in sequence.

2. The method of claim 1, wherein the first temperature is in a range from 1100° C. to 1300° C.

3. The method of claim 2, wherein the second temperature is in a range from 500° C. to 600° C.

4. The method of claim 1, wherein after the first protrusions are formed by partly etching the mask layer, a cover layer is formed on the first epitaxial layer and the first protrusions, and then the N-type epitaxial layer, the active layer and the P-type epitaxial layer are formed on the cover layer in sequence.

5. The method of claim 4, wherein the cover layer is grown on the first epitaxial layer and the first protrusions in the first temperature.

6. The method of claim 5, wherein the cover layer is an AlN layer.

7. The method of claim 1, wherein the first protrusions each have a diameter in a range from 2 μm to 3 μm.

8. The method of claim 1, wherein gaps each between two adjacent first protrusions have a diameter in a range from 1 μm to 2 μm.

9. The method of claim 1, wherein the substrate is made of sapphire, and an upper surface of the substrate has a plurality of second protrusions.

10. The method of claim 9, wherein the second protrusions each have a hexagon-shaped top surface arranged in a matrix.

11. The method of claim 1, wherein the substrate is made of sapphire, and the substrate has a flat upper surface.

12. The method of claim 1, wherein the N-type epitaxial layer, the active layer and the P-type epitaxial layer each are made of a material selected from a group consisting of GaN, AlGaN, InGaN and AlInGaN.

13. The method of claim 1, wherein the second epitaxial layer and the first epitaxial layer are etched by inductively coupled plasma etching or reactive ion etching.

14. A method for epitaxial growth of a light emitting diode, comprising following steps:
providing a substrate;
forming a buffer layer on the substrate;
forming a first epitaxial layer on the buffer layer in a first temperature;
forming a second epitaxial layer on the first epitaxial layer in a second temperature, the second temperature being lower than the first temperature to form a first rough surface on the second epitaxial layer;
etching the second epitaxial layer and the first epitaxial layer until the second epitaxial layer is totally etched away and a second rough surface is formed on the first epitaxial layer;
forming a mask layer on the rough surface of the first epitaxial layer;
partly etching the mask layer to form a plurality of first protrusions with the first epitaxial layer exposed thereamong; and
forming an N-type epitaxial layer, an active layer and a P-type epitaxial layer on the first epitaxial layer in sequence.

15. The method of claim 14, wherein the first temperature is in a range from 1100° C. to 1300° C.

16. The method of claim 15, wherein the second temperature is in a range from 500° C. to 600° C.

17. The method of claim 14, wherein after the first protrusions are formed by partly etching the mask layer, a cover layer is formed on the first epitaxial layer and the mask layer, the N-type epitaxial layer, the active layer and the P-type epitaxial layer are formed on the cover layer in sequence.

18. The method of claim 17, wherein the cover layer is grown on the first epitaxial layer and the mask layer in the first temperature.
